(19) United States
(12) Patent Application Publication
(10) Pub. No.: US 2025/0060672 A1
(43) Pub. Date: Feb. 20, 2025

(54) PHOTOLITHOGRAPHY METHOD USING CASTELLATION SHAPED ASSIST FEATURES TO FORM A LINE-AND-SPACE PATTERN AND PHOTOMASK CONTAINING THE ASSIST FEATURES

(71) Applicant: WESTERN DIGITAL TECHNOLOGIES, INC.,, SAN JOSE, CA (US)

(72) Inventor: Shinichi HISADOME, Yokkaichi (JP)

(21) Appl. No.: 18/451,206

(22) Filed: Aug. 17, 2023

(51) Int. Cl. G03F 7/20; G03F 1/38; G03F 1/80; G03F 7/00

(52) U.S. Cl. CPC G03F 7/2037; G03F 1/38; G03F 1/80; G03F 7/70625

(57) ABSTRACT

A method of patterning a structure includes applying a photoresist layer over a material layer located over substrate, lithographically exposing the photoresist layer by passing an exposure radiation beam through a photomask, developing the exposed photoresist layer, and etching the material layer using the developed photoresist layer as a mask. The photomask contains a photomask pattern including a combination of a line-and-space pattern and a peripheral castellation pattern. The peripheral castellation pattern includes a combination of an end straight line dummy pattern and a plurality of hammerhead patterns attached to a lengthwise sidewall of the end straight line dummy pattern.

### FIELD

The present disclosure relates generally to photolithography methods and photomasks, and particularly to a photolithography method of exposing and developing a line-and-space pattern using castellation shaped assist features and a photomask containing these assist features.

### BACKGROUND

The lithographic process margin for printing active lines at a peripheral region of a line-and-space pattern may be increased employing various lithographic techniques such as adding line-and-space gradation pattern that prints non-active (i.e., dummy) lines. As the pitch of the line-and-space pattern shrinks, the size of the line-and-space gradation pattern increases, which leads to a decrease in areas that can be used to form active devices. Thus, adding a line-and-space gradation pattern can result in formation of a large unusable dummy area on a substrate.

### SUMMARY

According to an aspect of the present disclosure, a method of patterning a structure includes applying a photoresist layer over a material layer located over substrate, lithographically exposing the photoresist layer by passing an exposure radiation beam through a photomask, developing the exposed photoresist layer, and etching the material layer using the developed photoresist layer as a mask. The photomask contains a photomask pattern including a combination of a line-and-space pattern and a peripheral castellation pattern. The peripheral castellation pattern includes a combination of an end straight line dummy pattern and a plurality of hammerhead patterns attached to a lengthwise sidewall of the end straight line dummy pattern.

According to another aspect of the present disclosure, a lithographic photomask comprises a transparent substrate, and a photomask pattern including a combination of a line-and-space pattern and a peripheral castellation pattern, wherein the peripheral castellation pattern comprises a combination of an end straight line dummy pattern and a plurality of hammerhead patterns attached to a lengthwise sidewall of the end straight line dummy pattern.

According to yet another aspect of the present disclosure, a semiconductor device comprises a substrate and a patterned material layer located over the substrate. The patterned material layer comprises: a line-and-space pattern structure having a uniform pitch and including a plurality of parallel active line structures that laterally extend along a first horizontal direction, and a peripheral castellation pattern structure. The peripheral castellation pattern structure comprises a combination of an end straight line dummy pattern structure and a plurality of hammerhead pattern structures attached to a lengthwise sidewall of the end straight line dummy pattern structure.

### BRIEF DESCRIPTION OF THE DRAWINGS

FIG. 1 is a schematic vertical cross-sectional view of a portion of an exemplary structure according to an embodiment of the present disclosure.

FIG. 2A is a top-down view of a first exemplary photomask according to a first embodiment of the present disclosure.

FIG. 2B is a vertical cross-sectional view of the first exemplary photomask along the vertical plane B-B′ of FIG. 2A.

FIG. 3A is a top-down view of a second exemplary photomask according to a second embodiment of the present disclosure.

FIG. 3B is a vertical cross-sectional view of the second exemplary photomask along the vertical plane B-B′ of FIG. 3A.

FIG. 4 schematically illustrates a lithographic exposure tool that can be employed to lithographically expose a photoresist layer on a substrate according to an embodiment of the present disclosure.

FIG. 5A is a vertical cross-sectional view of an exemplary structure after lithographically patterning the photoresist layer according to an embodiment of the present disclosure.

FIG. 5B is a top-down view of the exemplary structure of FIG. 5A. The vertical plane A-A′ is the cut plane of the vertical cross-sectional view of FIG. 5A.

FIG. 6 is a vertical cross-sectional view of the exemplary structure after performing an anisotropic etch process according to an embodiment of the present disclosure.

FIG. 7A is a vertical cross-sectional view of an exemplary structure after removing the photoresist layer according to an embodiment of the present disclosure.

FIG. 7B is a top-down view of the exemplary structure of FIG. 7A. The vertical plane A-A′ is the cut plane of the vertical cross-sectional view of FIG. 7A.

### DETAILED DESCRIPTION

As discussed above, the embodiments of the present disclosure are directed to a photolithography method of exposing and developing a line-and-space pattern using castellation shaped assist features on a photomask, the various aspects of which are described below. The castellation shaped assist features provide a more area-effective way of printing the line-and-space pattern with reduced pattern deformation in edge regions. Embodiments of the disclosure can be employed to form various solid state devices, such as semiconductor devices containing a line-and-space pattern (e.g., a bit line pattern for a semiconductor memory device, etc.).

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

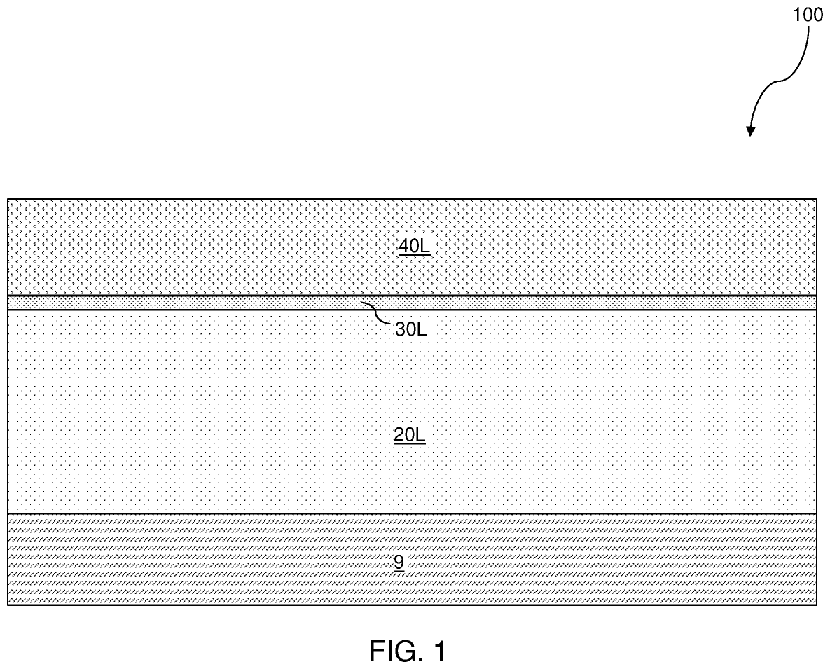

Referring to FIG. 1, a portion of an exemplary structure according to an embodiment of the present disclosure is illustrated. The exemplary structure 100 includes a substrate 9, a material layer 20L, an optional anti-reflective coating (ARC) layer 30L, and a photoresist layer 40L. The substrate 9 may comprise any suitable solid state device substrate known in the art. For example, the semiconductor substrate 9 may comprise a commercially available semiconductor wafer, such as a single-crystalline silicon wafer. The material layer 20L may comprise at least one insulating material, at least one semiconducting material, and/or at least one conductive material, that will be patterned into a line-and-space pattern. The material layer 20L may comprise a stack of multiple material layers (not individually shown). For example, the material layer 20L may comprise an electrically conductive layer (e.g., a metal layer, such as Cu, W, Al, etc.) that is to be patterned into a plurality of bit lines for a memory device. The ARC layer 30L may comprise at least one anti-reflective coating layer known in the art, such as silicon nitride or titanium oxide. The photoresist layer 40L comprises a layer of a photosensitive material. The photoresist layer 40L may comprise a deep ultraviolet (DUV) photoresist material, a mid-ultraviolet (MUV) photoresist material, or an extreme ultraviolet (EUV) photoresist material. The photoresist layer 40L may comprise a positive photoresist material or a negative photoresist material.

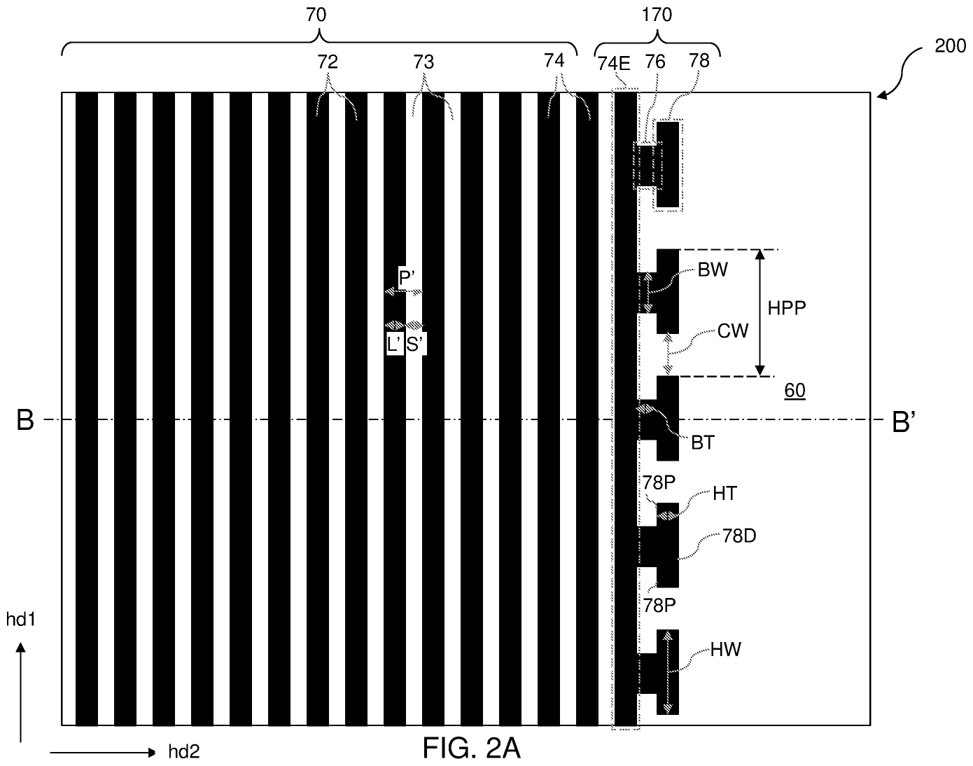

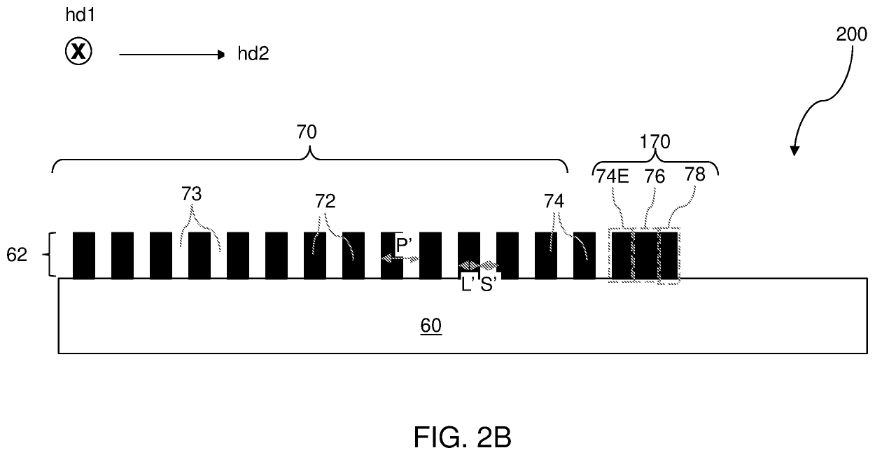

Referring to FIGS. 2A and 2B, a first exemplary photomask 200 according to an embodiment of the present disclosure is illustrated. The first exemplary photomask 200 can be a lithographic photomask 200 (i.e., a photomask employed for lithographic processing), such as a lithographic reticle which is laterally stepped over the photoresist layer 40L covered substrate 9 during a photolithographic exposure process.

The first exemplary photomask 200 can include a transparent substrate 60 and a radiation opaque photomask pattern (70, 170) including a combination of a line-and-space pattern 70 and a peripheral castellation pattern 170. The transparent substrate 60 may comprise a glass or quart substrate, and the photomask patterns (70, 170) may comprise a metal pattern, such as a chromium pattern, on the transparent substrate 60. As used herein, a line-and-space pattern refers to a pattern in which a unit pattern including a uniform line and a uniform spacing is repeated with a periodicity along a horizontal direction that is perpendicular to the lengthwise direction of the uniform line. The line-and-space pattern is a basic pattern that is employed in semiconductor manufacturing to form a one-dimensional periodic array of line structures. As used herein, a castellation pattern refers to a pattern of evenly spaced gaps or notches in a laterally-extending structure. A peripheral castellation pattern refers to a castellation pattern that is formed at a periphery of another pattern, such as a line pattern.

In one embodiment, the line-and-space pattern 70 and the peripheral castellation pattern 170 may comprise patterned portions of an optically opaque film (e.g., Cr film) 62 located within areas of the line-and-space pattern 70 and the peripheral castellation pattern 170. The line-and-space pattern 70 comprises a plurality of active line patterns 72 and dummy line patterns 74 separated by spaces 73 in the opaque film 62 over the transparent substrate 60. The dummy line patterns 74 may be located at an edge of the line-and-space pattern 70. The line patterns (72, 74) comprise strips of the opaque film 62 having a uniform line width L′ that are laterally spaced from each other by a uniform spacing S′ of the spaces 73. The strips of the opaque film 62 laterally extend along a first horizontal direction hd1, and are laterally spaced from each other by the spaces 73 along a second horizontal direction hd2 that is perpendicular to the first horizontal direction hd1.

The line width L′ of the line pattern (72, 74) in the lithographic photomask 200 is the line width of a lithographic pattern to be formed in the photoresist layer 40L times the image reduction factor of a lithographic system to be employed to transfer the pattern in the lithographic photomask 200 to the photoresist layer 40L. Typically, the image reduction factor is in a range from 4 to 10. Thus, if the line width of the line-and-space pattern to be formed in the photoresist layer 40L is 50 nm, the line width L′ of the line pattern (72, 74) in the lithographic photomask 200 may be in a range from 200 nm to 500 nm. Likewise, the spacing S′ of the pattern of the spaces 73 in the lithographic photomask 200 is the spacing of the lithographic pattern to be formed in the photoresist layer 40L times the image reduction factor of the lithographic system to be employed to transfer the pattern in the lithographic photomask 200 to the photoresist layer 40L. If the spacing of the line-and-space pattern 70 to be formed in the photoresist layer 40L is 50 nm, the spacing S′ of the pattern of the spaces 73 in the lithographic photomask 200 may be in a range from 200 nm to 500 nm. The sum of the line width L′ and the uniform spacing S′ equals the pitch P′ of the line-and-space pattern 70 in the lithographic photomask 200. The line width L′ may be 20 nm to 1,000 nm, such as 50 nm to 500 nm. The uniform spacing S′ may be 20 nm to 1,000 nm, such as 50 nm to 500 nm. Thus, the pitch P′ may be 40 nm to 2,000 nm, such as 100 nm to 1,000 nm. However, lesser or greater dimensions may also be used. The total number of line patterns (72, 74) in the line-and-space pattern in the lithographic photomask 200 may be in a range from 10 to 1,000,000, although lesser and greater numbers may also be employed. The number of dummy line patterns 74 may be 2 to 20, while the number active line patterns 72 may be greater than the number of dummy line patterns 74.

The peripheral castellation pattern 170 comprises a combination of the end straight dummy line pattern 74E and a plurality of dummy hammerhead patterns (76, 78) attached to a lengthwise sidewall of the end straight dummy line pattern 74E facing away from the active line patterns 72 of the line-and-space pattern 70. The straight dummy line pattern 74 may be identical to the line patterns (72, 74) in the line-and-space pattern 70. The spacing S′ of the space 73 between the end straight dummy line pattern 74E and an adjacent line pattern (72 or 74) may be the same as the spacing S′ of the spaces 73 within the line-and-space pattern 70.

In one embodiment, each hammerhead pattern (76, 78) comprises: a respective “hammerhead” first rectangular pattern 78 having a hammerhead width HW along a first horizontal direction hd1 that is parallel to the lengthwise direction of the end straight dummy line pattern 74E; and a respective “bridge” second rectangular pattern 76 having a bridge width BW along the first horizontal direction hd1 that is less than the hammerhead width HW. Each first rectangular pattern 78 may have a distal lengthwise sidewall 78D that is parallel to the first horizontal direction hd1, and a pair of proximal lengthwise sidewalls 78P that are laterally spaced apart from each other by a respective second rectangular pattern 76 and are adjoined to the respective second rectangular pattern 76.

In one embodiment, neighboring pairs of first rectangular patterns 78 are laterally spaced from each other along the first horizontal direction hd1 by a cut width CW that is less than the hammerhead width HW. In one embodiment, the ratio of the cut width CW to the bridge width BW may be in a range from 1.0 to 1.5. In one embodiment, the ratio of the hammerhead width HW to the cut width CW may be in a range from 1.5 to 3.0, and the ratio of the hammerhead width HW to the bridge width BW may be in a range from 1.8 to 3.6.

In one embodiment, the first rectangular patterns 78 have a hammerhead thickness HT along a second horizontal direction hd2 that is perpendicular to the first horizontal direction hd1. In one embodiment, the second rectangular patterns 76 have a bridge thickness BT along the second horizontal direction hd2 that is the same as the hammerhead thickness HT. In one embodiment, the end straight dummy line pattern 74E has a uniform width along the second horizontal direction hd2 that is the same as the hammerhead thickness HT and the bridge thickness BT. In one embodiment, the line-and-space pattern 70 comprises line patterns (72, 74) having a uniform line width L′ along the second horizontal direction hd2 as the uniform width of the end straight dummy line pattern 74E.

In one embodiment, the plurality of hammerhead patterns (76, 78) comprises a periodic repetition of a unit hammerhead pattern (76, 78) that is repeated along a first horizontal direction hd1 with a hammerhead pattern pitch HPP. In one embodiment, the ratio of the hammerhead pattern pitch HPP and a pitch P′ of the line-and-space pattern 70 may be in a range from 2.0 to 5.0.

In one embodiment, the lateral spacing between the end straight dummy line pattern 74E and a most proximal line pattern (72 or 74) within the line-and-space pattern 70 may be the same as a spacing between neighboring pairs of active line patterns 72 within the line-and-space pattern 70.

In one embodiment, no other pattern is present in proximity to the peripheral castellation pattern 170 besides the line-and-space pattern 70 up to the lateral distance of three times the pitch P′ of the line-and-space pattern 70. Thus, in one embodiment, sublithographic assist features (SLAF) or half-tone structures may be omitted in lithographic photomask 200.

In a non-limiting illustrative example, the uniform line width L′ of the line patterns (72, 74) of the line-and-space pattern 70 may be a unit dimension of the lithographic photomask 200, each spacing S′ of the spaces 73 of the line-and-space pattern 70 may be the unit dimension of the lithographic photomask 200, the uniform width of the end straight dummy line pattern 74E may be the unit dimension of the lithographic photomask 200, the hammerhead thickness HT may be the unit dimension of the lithographic photomask 200, the bridge thickness BT may be the unit dimension of the lithographic photomask 200, the hammerhead width HW may be 4 times the unit dimension of the lithographic photomask 200, the bridge width BW may be 1.6 times the unit dimension of the lithographic photomask 200, the cut width CW may be 2 times the unit dimension of the lithographic photomask 200, and the hammerhead pattern pitch HPP may be 6 times the unit dimension of the lithographic photomask 200.

The unit dimension of the lithographic photomask 200 is the same as the product of the image reduction factor of the lithographic system and a unit dimension of a lithographic pattern to be formed in the photoresist layer 40L. The lithographic pattern to be formed in the photoresist layer 40L may be in a range from 5 nm to 200 nm, such as from 20 nm to 100 nm. The image reduction factor is typically in a range from 4 to 10. Thus, the unit dimension of the lithographic photomask 200 may be in a range from 20 nm to 2,000 nm, such as from 100 nm to 1,000 nm, although lesser and greater unit dimensions may also be employed for the lithographic photomask 200. For example, if the unit dimension is 50 nm, then L′=50 nm, S′=50 nm, HT=50 nm, BT=50 nm, HW=200 nm, BW=80 nm, CW=100 nm, and HPP=300 nm.

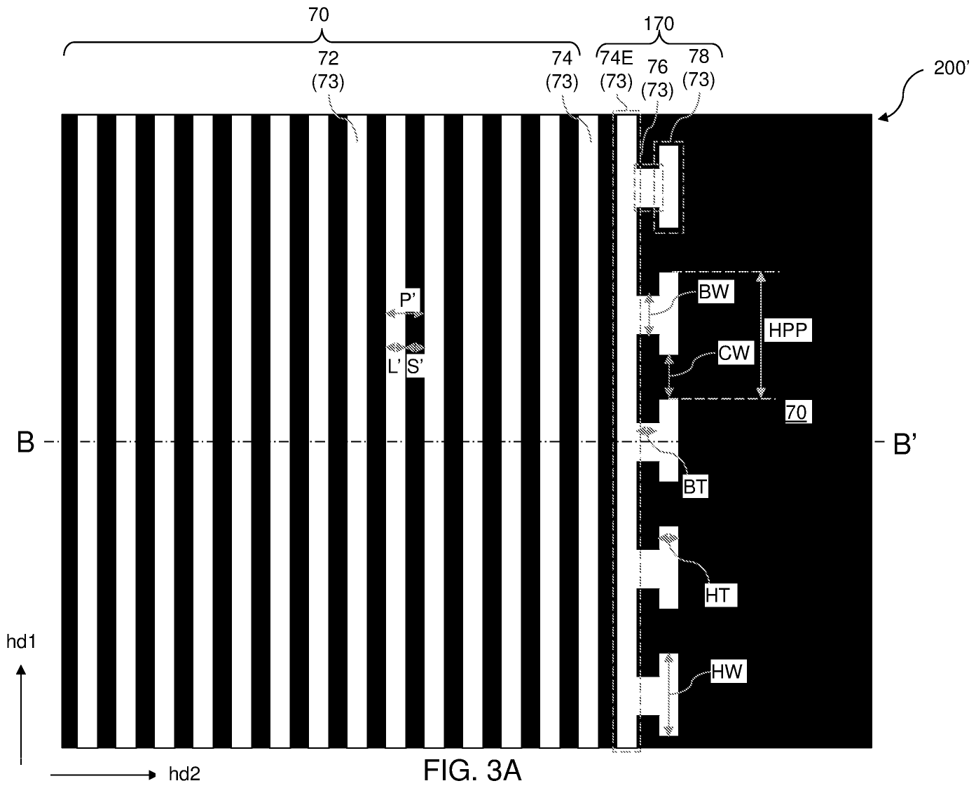

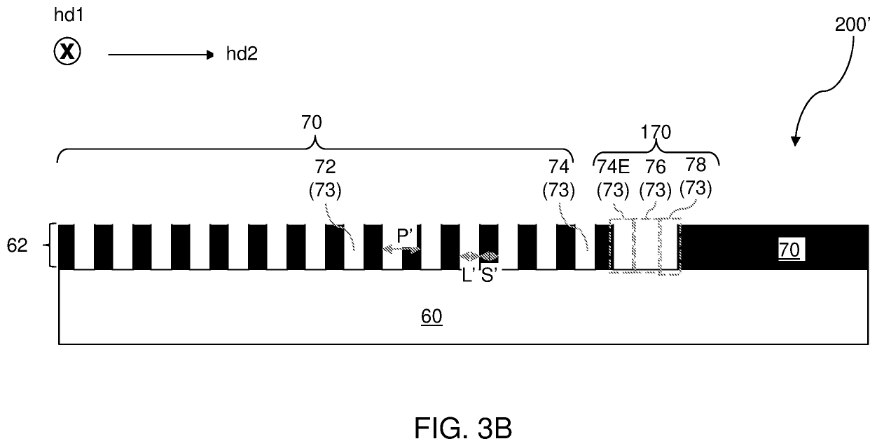

Referring to FIGS. 3A and 3B, a second exemplary photomask 200′ according to an embodiment of the present disclosure is illustrated. The second exemplary photomask 200′ can be derived from the first exemplary photomask 200 illustrated in FIGS. 2A and 2B by reversing the polarity of the lithographic pattern in the first exemplary photomask 200. In other words, the opaque areas in the first exemplary photomask 200 become transparent areas in the second exemplary photomask 200′, and the transparent areas in the first exemplary photomask 200 become opaque areas in the second exemplary photomask 200′. In this case, the line-and-space pattern 70 and the peripheral castellation pattern 170 may comprise areas of openings 73 in an optically opaque film 62 that covers the transparent substrate 60. The areas that do not correspond to the line-and-space pattern 70 and the peripheral castellation pattern 170 are covered by the optically opaque film 62 in the second exemplary photomask 200′.

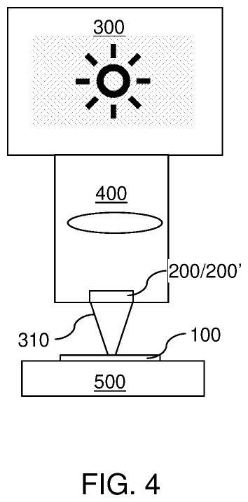

Referring to FIG. 4, a lithographic exposure tool is illustrated, which can be employed to lithographically expose the photoresist layer 40L on the substrate 9. The lithographic exposure tool includes a radiation source 300 that generates an ultraviolet radiation, which may comprise a mid-ultraviolet radiation, a deep ultraviolet radiation, or an extreme ultraviolet radiation (EUV). An optics system 400 comprises lenses or other optical components, and guides the ultraviolet radiation generated by the radiation source 300 through a lithographic photomask, which may be any of the first exemplary photomask 200 or the second exemplary photomask 200′ described above. A focused exposure beam 310 passes through the lithographic photomask (200, 200′), and impinges on a top surface of the photoresist layer 40L located over the substrate 9 of the structure described with reference to FIG. 1. The structure 100 may be positioned over a wafer stage 500, which may be configured to move laterally and/or vertically to align the location of lithographic exposure beam 310 with the underlying photoresist layer 40L. For example, if the lithographic photomask comprises a reticle, then the wafer stage 500 may be moved relative to the reticle to sequentially expose different areas of the photoresist layer 40L with the lithographic exposure beam 310.

In summary, a photoresist layer 40L can be applied over a material layer 20L located over a substrate 9. The photoresist layer 40L can be lithographically exposed by passing a focused illumination beam 310 through a photomask 200 while the photoresist layer 40L is located at or in proximity to a focal point of the focused illumination beam 310. The photomask 200 comprises a photomask pattern (70, 170) including a combination of a line-and-space pattern 70 and a peripheral castellation pattern 170. The peripheral castellation pattern 170 comprises a straight line pattern 74 (e.g., the end straight dummy line pattern 74E) and a plurality of hammerhead patterns (76, 78) attached to a lengthwise sidewall of the straight line pattern 74. If the photoresist layer 40L comprises a positive photoresist material, then the first exemplary photomask 200 may be employed for the lithographic exposure process. Alternatively, if the photoresist layer 40L comprises a negative photoresist material, then the second exemplary photomask 200′ may be employed for the lithographic exposure process.

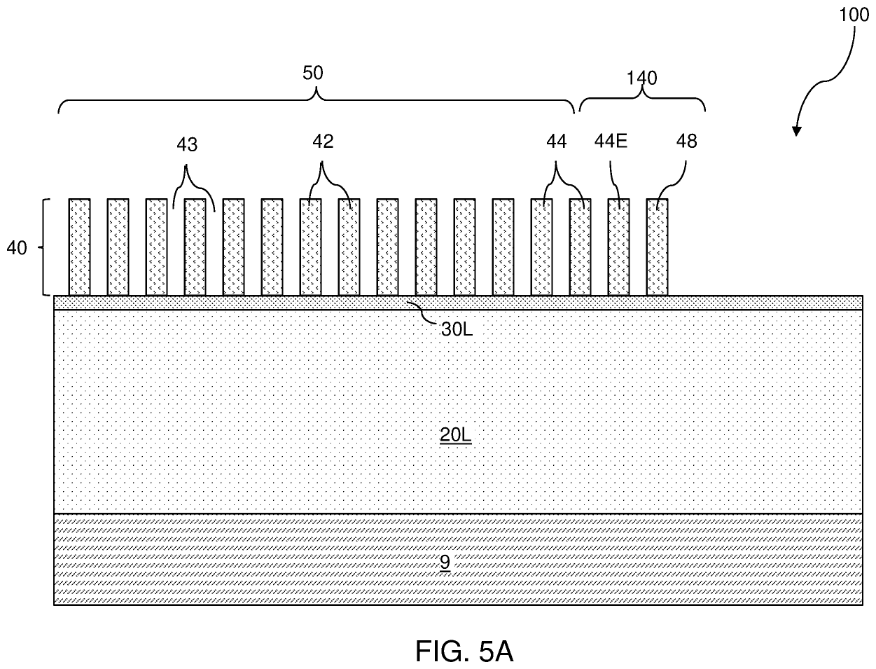

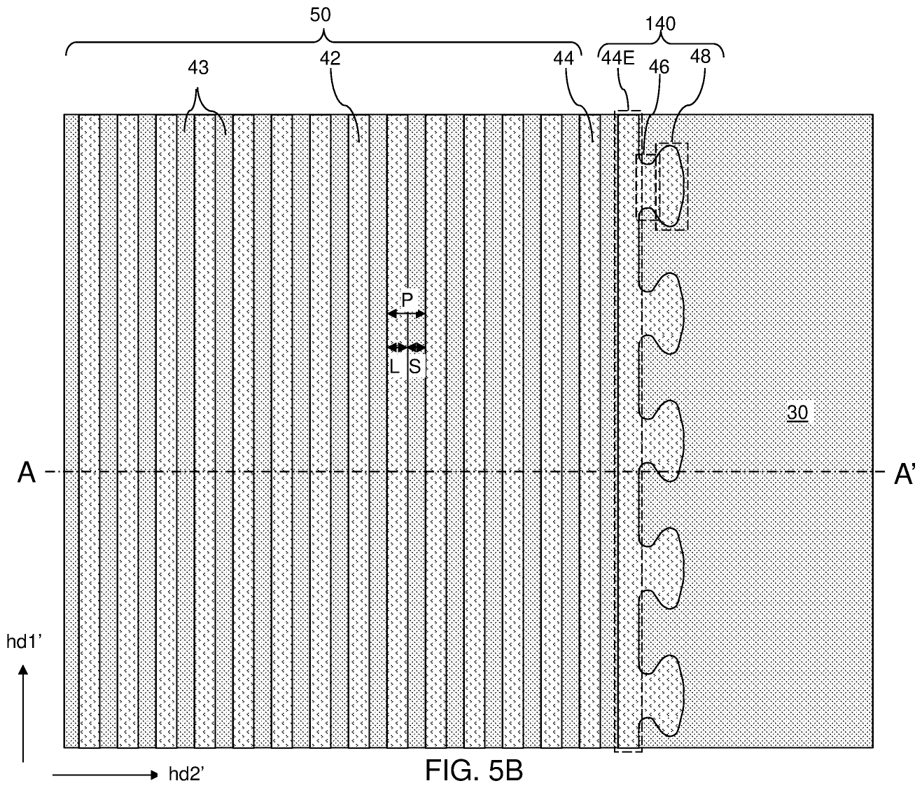

Referring to FIGS. 5A and 5B, the exemplary structure 100 including the substrate 9, the material layer 20L, the optional ARC layer 30L, and a patterned photoresist layer 40 is illustrated after lithographic exposure and development.

The patterned photoresist layer 40 comprises line-and-space photoresist pattern 50 and a peripheral castellation photoresist pattern 140. The line-and-space photoresist pattern 50 comprises a plurality of active line patterns 42 and dummy line patterns 44 that are strips of a photoresist material having a uniform line width L and laterally spaced from each other by spaces 43 having a uniform spacing S. The strips of the photoresist material laterally extend along a first horizontal direction hd1′, and are laterally spaced from each other along a second horizontal direction hd2′ that is perpendicular to the first horizontal direction hd1′. The sum of the line width L and the uniform spacing S equals the pitch P of the line-and-space pattern 50 in the patterned photoresist layer 40.

The peripheral castellation photoresist pattern 140 comprises a combination of an end straight line dummy photoresist pattern 44E and a plurality of hammerhead photoresist patterns (46, 48) attached to a lengthwise sidewall of the end straight line dummy photoresist pattern 44E. The end straight line dummy photoresist pattern 44 may be identical to the active and dummy line patterns (42, 44) in the line-and-space photoresist pattern 50. The spacing between the line patterns in the line-and-space photoresist pattern 50 and the end straight line dummy photoresist pattern 44 and the adjacent line pattern (42 or 44) may be the same as the spacing S within the line-and-space photoresist pattern 50.

In one embodiment, each of the hammerhead photoresist patterns (46, 48) comprises: a respective “head” oval-shaped photoresist pattern 48 having a laterally-convex sidewall that extends along the first horizontal direction hd1′ that is parallel to the lengthwise direction of the end straight line dummy photoresist pattern 44E; and a respective “bridge” photoresist pattern 46 having a lesser dimension along the first horizontal direction hd1 than the respective oval-shaped photoresist pattern 48. The bridge photoresist pattern 46 may have a pair of laterally-concave sidewalls. As used herein, a laterally-convex surface refers to a surface having a convex horizontal cross-sectional profile, and a laterally-concave surface refers to a surface having a concave horizontal cross-sectional profile.

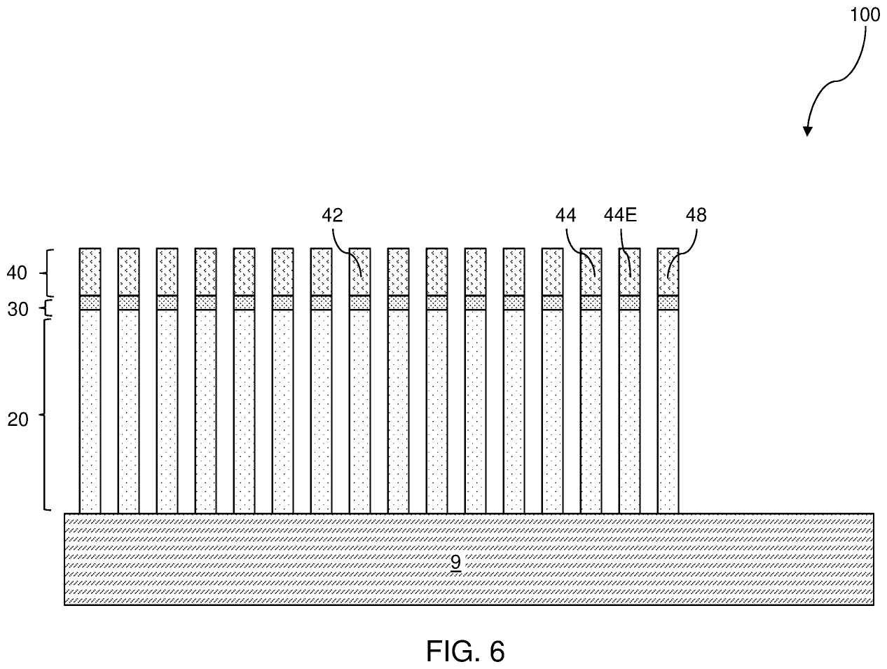

Referring to FIG. 6, an anisotropic etch process can be performed to transfer the pattern in the patterned photoresist layer 40 through the optional ARC layer 30L and the material layer 20L. The etch chemistry of the anisotropic etch process may be suitably selected to enable etching of unmasked portions of the ARC layer 30L and the material layer 20L. The thickness of the material layer 20L may be in a range from 10 nm to 10,000 nm, such as from 100 nm to 2,000 nm, although lesser and greater thicknesses may also be employed. The ARC layer 30L is converted into a patterned ARC layer 30, and the material layer 20L is converted into a patterned material layer 20.

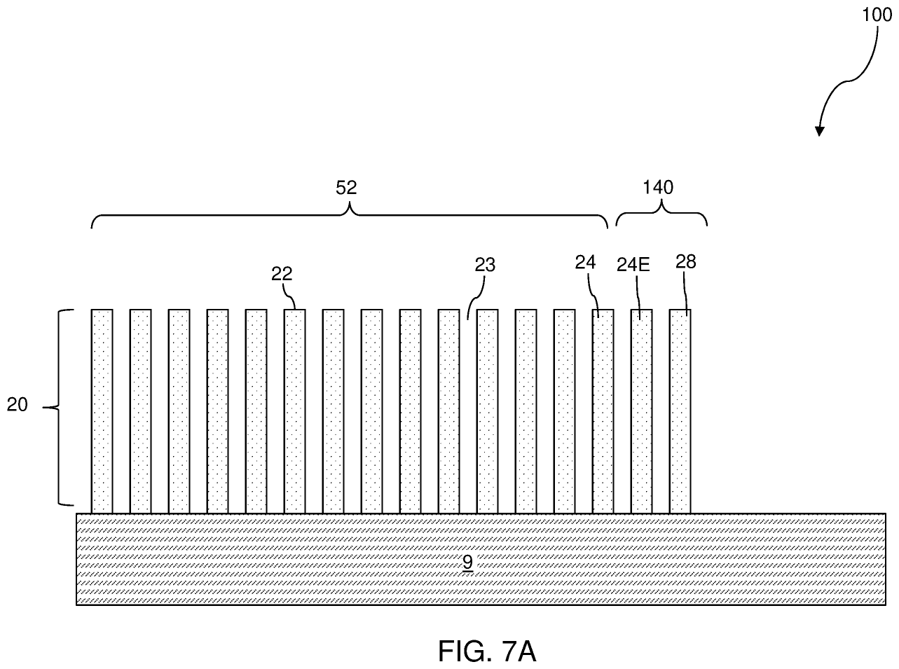

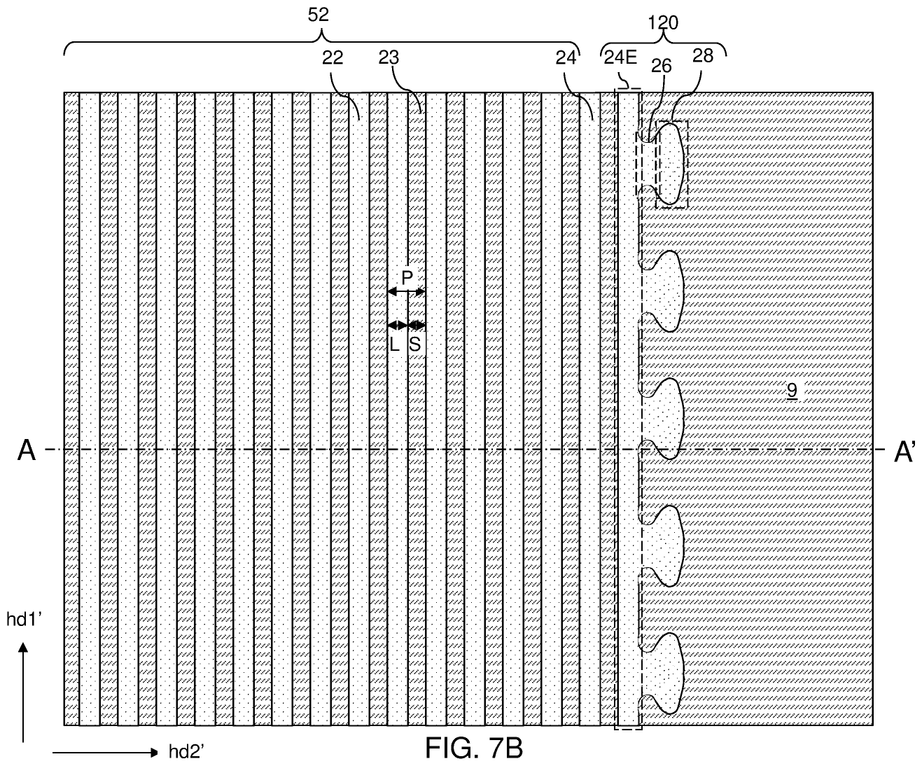

Referring to FIGS. 7A and 7B, the patterned photoresist layer 40 and the patterned ARC layer 30 can be removed, for example, by ashing. A patterned structure 100 is provided, which may comprise a substrate 9 and a patterned material layer 20 located over the substrate 9. In one embodiment, the patterned material layer 20 comprises: a line-and-space pattern structure 52 having a uniform pitch P and including a plurality of parallel active line structures 22 and dummy line structures 24 that laterally extend along a first horizontal direction hd1′, and a peripheral castellation pattern structure 120. The parallel line structures (22, 24) may have a uniform width L, and may be laterally spaced apart from each other by a uniform spacing S. The uniform pitch P can be the same as the sum of the uniform width L and the uniform spacing S.

In one embodiment, the peripheral castellation pattern structure 120 comprises a combination of an end straight dummy line pattern 24E structure and a plurality of hammerhead pattern structures (26, 28) attached to a lengthwise sidewall of the end straight dummy line pattern structure 2E4. In one embodiment, each of the hammerhead pattern structures (26, 28) comprises: a respective “head” oval-shaped material portion 28 that is laterally elongated along the first horizontal direction hd1 and comprises a respective laterally-convex sidewall; and a respective “bridge” material portion 26 connecting the respective oval-shaped material portion 28 to the end straight dummy line pattern structure 24E. The bridge material portion 26 comprises a respective pair of laterally-concave sidewalls.

In one embodiment, the patterned material layer 20 is free of any geometrical pattern within an area of that is located on an opposite side of the line-and-space pattern structure 52 with respect to the peripheral castellation pattern structure 120 and is located within a lateral distance from the peripheral castellation pattern structure 120 that is less than three times the uniform pitch P of the line-and-space pattern structure 52. In other words, there is a space laterally facing the hammerhead pattern structures (26, 28) that has a lateral width along the second horizontal direction hd2′ that is at least 3P.

The various embodiments of the present disclosure can be employed to form a one-dimensional periodic structure including a line-and-space pattern while minimizing dummy pattern lateral space. This increases overall active device density. In one embodiment, the lithographic photomask 200/200′ of the embodiments of the present disclosure does not include any sublithographic assist features or phase-shifting features, which reduces its manufacturing cost and complexity.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method of patterning a structure, comprising:
applying a photoresist layer over a material layer located over substrate;
lithographically exposing the photoresist layer by passing an exposure radiation beam through a photomask, wherein the photomask comprises a photomask pattern including a combination of a line-and-space pattern and a peripheral castellation pattern, and wherein the peripheral castellation pattern comprises a combination of an end straight line dummy pattern and a plurality of hammerhead patterns attached to a lengthwise sidewall of the end straight line dummy pattern;
developing the exposed photoresist layer; and
etching the material layer using the developed photoresist layer as a mask.

2. The method of claim 1, wherein each of the hammerhead patterns comprises:
a respective first rectangular pattern having a hammerhead width along a first horizontal direction that is parallel to a lengthwise direction of the end straight line dummy pattern; and
a respective second rectangular pattern connecting the first rectangular pattern to the end straight line dummy pattern, and having a bridge width along the first horizontal direction that is less than the hammerhead width.

3. The method of claim 2, wherein neighboring pairs of first rectangular patterns are laterally spaced from each other by a cut width that is less than the hammerhead width.

4. The method of claim 3, wherein a ratio of the cut width to the bridge width is in a range from 1 to 1.5.

5. The method of claim 3, wherein:
a ratio of the hammerhead width to the cut width is in a range from 1.5 to 3; and
a ratio of the hammerhead width to the bridge width is in a range from 1.8 to 3.6.

6. The method of claim 2, wherein:
the first rectangular patterns have a hammerhead thickness along a second horizontal direction that is perpendicular to the first horizontal direction; and
the second rectangular patterns have a bridge thickness along the second horizontal direction that is the same as the hammerhead thickness.

7. The method of claim 6, wherein the end straight line dummy pattern has a uniform width along the second horizontal direction that is the same as the hammerhead thickness and the bridge thickness.

8. The method of claim 7, wherein the line-and-space pattern comprises active and dummy line patterns having a uniform line width along the second horizontal direction which is the same as the uniform width of the end straight line dummy pattern.

9. The method of claim 1, wherein the plurality of hammerhead patterns comprise a periodic repetition of a unit hammerhead pattern that is repeated along a first horizontal direction with a hammerhead pattern pitch.

10. The method of claim 9, wherein a ratio of the hammerhead pattern pitch and a pitch of the line-and-space pattern is in a range from 2 to 5.

11. The method of claim 1, wherein a lateral spacing between the end straight line dummy pattern and a most proximal line pattern within the line-and-space pattern is the same as a spacing between neighboring pairs of line patterns within the line-and-space pattern.

12. The method of claim 1, wherein the photomask pattern includes an empty space facing the castellation pattern.

13. A lithographic photomask, comprising:
a transparent substrate; and
a photomask pattern including a combination of a line-and-space pattern and a peripheral castellation pattern, wherein the peripheral castellation pattern comprises a combination of an end straight line dummy pattern and a plurality of hammerhead patterns attached to a lengthwise sidewall of the end straight line dummy pattern.

14. The lithographic photomask of claim 13, wherein each of the hammerhead patterns comprises:
a respective first rectangular pattern having a hammerhead width along a first horizontal direction that is parallel to a lengthwise direction of the end straight line dummy pattern; and
a respective second rectangular pattern having a bridge width along the first horizontal direction that is less than the hammerhead width.

15. The lithographic photomask of claim 13, wherein the plurality of hammerhead patterns comprise a periodic repetition of a unit hammerhead pattern that is repeated along a first horizontal direction with a hammerhead pattern pitch.

16. The lithographic photomask of claim 13, wherein the line-and-space pattern and the peripheral castellation pattern comprise patterned portions of an optically opaque film located within areas of the line-and-space pattern and the peripheral castellation pattern.

17. The lithographic photomask of claim 13, wherein the line-and-space pattern and the peripheral castellation pattern comprise areas of openings in an optically opaque film that covers the transparent substrate.

18. A semiconductor device, comprising:
a substrate; and
a patterned material layer located over the substrate, wherein the patterned material layer comprises:
a line-and-space pattern structure having a uniform pitch and including a plurality of parallel active line structures that laterally extend along a first horizontal direction; and
a peripheral castellation pattern structure, wherein the peripheral castellation pattern structure comprises a combination of an end straight line dummy pattern structure and a plurality of hammerhead pattern structures attached to a lengthwise sidewall of the end straight line dummy pattern structure.

19. The semiconductor device of claim 18, wherein the parallel active line structures comprise bit lines of the semiconductor device.

20. The semiconductor device of claim 18, wherein each of the hammerhead pattern structures comprises:
a respective oval-shaped material portion that is laterally elongated along the first horizontal direction and comprising a respective laterally-convex sidewall; and
a respective bridge material portion connecting the respective oval-shaped material portion to the end straight line dummy pattern structure and comprising a respective pair of laterally-concave sidewalls.
